(19) United States
(12) Patent Application Publication
(10) Pub. No.: US 2015/0177306 A1
(43) Pub. Date: Jun. 25, 2015

(54) Validation of Capacitor Bank Operation

(71) Applicants: Troy Hedlund, Rogers, MN (US); Tobin Sobaski, Woodbury, NM (US); Dean Hotver, Excelsior, MN (US); Derek Guenther, St. Paul, MN (US); Prasanna Anbazhagan, Maple Grove, MN (US)

(72) Inventors: Troy Hedlund, Rogers, MN (US); Tobin Sobaski, Woodbury, NM (US); Dean Hotver, Excelsior, MN (US); Derek Guenther, St. Paul, MN (US); Prasanna Anbazhagan, Maple Grove, MN (US)

(73) Assignee: COOPER TECHNOLOGIES COMPANY, Houston, TX (US)

(21) Appl. No.: 14/138,264

(22) Filed: Dec. 23, 2013

(51) Int. Cl. G01R 31/02; H01G 4/38

(52) U.S. Cl. CPC G01R 31/028; H01G 4/38

(57) ABSTRACT

A system for validating an operation of a capacitor bank is disclosed. The system can include a first capacitor of the capacitor bank electrically coupled to a first power line. The system can also include a first sensor operatively coupled to the first power line, where the first sensor is configured to measure a first representation of power flowing through the first power line. The system can further include a local control system communicably coupled to the first sensor, where the local control system receives the first representation of the power flowing through the first power line from the first sensor, where the local control system validates the operation of the first capacitor based on the first representation.

### TECHNICAL FIELD

Embodiments described herein relate generally to capacitor banks, and more particularly to systems, methods, and devices for validating the operation of a three-phase capacitor bank.

### BACKGROUND

Capacitor banks can serve one or more of a number of purposes. For example, a capacitor bank can be used to provide volt-amp reactive (VAR) support for an alternating current (AC) electric circuit. As another example, a capacitor bank can be used to improve power flow through an electric system to which the capacitor bank is electrically coupled. As yet another example, a capacitor bank can be used to maintain a desired voltage profile. As yet another example, a capacitor bank can be used to improve a ripple current capacity of a power supply for a direct current (DC) circuit. As still another example, a capacitor bank can be used to improve the power factor for power flowing through a corresponding electric system.

When used in power transmission and/or distribution system applications, capacitor banks may not always be operating. Instead, the one or more capacitors within a capacitor bank are turned on and off at various times when needed. Under these conditions, it can be difficult to determine whether one or more capacitors within the capacitor bank have functioned properly. This can especially be true in an interconnected transmission and/or distribution network, where a number of different capacitor banks can be electrically interconnected to each other. In such a case, if one capacitor or capacitor bank fails to operate properly, it can be difficult to determine which capacitor or capacitor bank among the interconnected network caused a resulting problem, such as a phase imbalance.

### SUMMARY

In general, in one aspect, the disclosure relates to a system for validating an operation of a capacitor bank. The system can include a first capacitor of the capacitor bank electrically coupled to a first power line. The system can also include a first sensor operatively coupled to the first power line, where the first sensor is configured to measure a first representation of power flowing through the first power line. The system can also include a local control system communicably coupled to the first sensor, where the local control system receives the first representation of the power flowing through the first power line from the first sensor, where the local control system validates the operation of the first capacitor based on the first representation.

In another aspect, the disclosure can generally relate to a method for validating an operation of a capacitor bank. The method can include a hardware processor and a validation engine executing on the hardware processor. The validation engine can be configured to receive a command received by the first capacitor, where the command instructs the first capacitor to change from a first state to a second state. The validation engine can also be configured to receive the first representation from the first sensor. The validation engine can further be configured to determine, based on the first representation, whether the first capacitor changes from the first state to the second state. The validation engine can also be configured to send a notification to a master controller when the first capacitor fails to change from the first state to the second state in response to the command.

In another aspect, the disclosure can generally relate to a computer readable medium that includes computer readable program code embodied therein for performing a method of validating an operation of a capacitor bank. The method can include receiving a first representation from a first sensor at a first time, where the first sensor is operatively coupled to a first power line, where the first power line is electrically coupled to a first capacitor of the capacitor bank. The method can also include determining, based on the first representation, whether the first capacitor of the capacitor bank has changed from a first state to a second state. The method can further include sending a first notification to a master controller, where the first notification includes information as to whether the first capacitor of the capacitor bank has changed from the first state to the second state.

These and other aspects, objects, features, and embodiments will be apparent from the following description and the appended claims.

### BRIEF DESCRIPTION OF THE DRAWINGS

The drawings illustrate only example embodiments of validating the operation of some or all of a capacitor bank and are therefore not to be considered limiting of its scope, as validating the operation of a capacitor bank may admit to other equally effective embodiments. The elements and features shown in the drawings are not necessarily to scale, emphasis instead being placed upon clearly illustrating the principles of the example embodiments. Additionally, certain dimensions or positionings may be exaggerated to help visually convey such principles. In the drawings, reference numerals designate like or corresponding, but not necessarily identical, elements.

FIGS. 1A and 1B show various views of an example local system that validates an operation of a capacitor bank in accordance with certain example embodiments.

FIG. 2 shows a system that includes a number of local systems as shown in FIGS. 1A and 1B that are connected to a master system in accordance with certain example embodiments.

FIG. 3 shows a diagram of a system in accordance with one or more example embodiments.

FIG. 4 shows a flowchart of a method in accordance with one or more example embodiments.

FIG. 5 shows a computing device in accordance with one or more example embodiments.

### DETAILED DESCRIPTION OF EXAMPLE EMBODIMENTS

The example embodiments discussed herein are directed to systems, apparatuses, and methods of validating the operation of some or all of a capacitor bank. While the Figures shown and described herein are directed to validating the operation of one or more capacitors in a three-phase capacitor bank, the operation of one or more capacitors or capacitor banks for a number of phases other than three phases (e.g., single phase) can also be validated using example embodiments described herein. Thus, the examples of validating the operation of a capacitor bank described herein are not limited to three phase power configurations.

The components of example systems for validating the operation of a capacitor bank described herein can be physically placed in outdoor environments. Thus, the components of systems for validating the operation of a capacitor bank can be subject to extreme heat, extreme cold, moisture, humidity, high winds, dust, and other conditions that can cause wear on such components. In certain example embodiments, the components of example systems for validating the operation of a capacitor bank, as well as any coupling (e.g., mechanical, electrical) between such components, are made of materials that are designed to maintain a long-term useful life and to perform when required without mechanical failure.

Example embodiments of systems for validating the operation of a capacitor bank will be described more fully hereinafter with reference to the accompanying drawings, in which example embodiments of systems for validating the operation of a capacitor bank are shown. Systems for validating the operation of a capacitor bank may, however, be embodied in many different forms and should not be construed as limited to the example embodiments set forth herein. Rather, these example embodiments are provided so that this disclosure will be thorough and complete, and will fully convey the scope of systems for validating the operation of a capacitor bank to those of ordinary skill in the art. Like, but not necessarily the same, elements (also sometimes called components) in the various figures are denoted by like reference numerals for consistency. Terms such as “first,” “second,” “top,” “base,” “open,” and “closed” are used merely to distinguish one component (or part of a component or state of a component) from another. Such terms are not meant to denote a preference or a particular orientation.

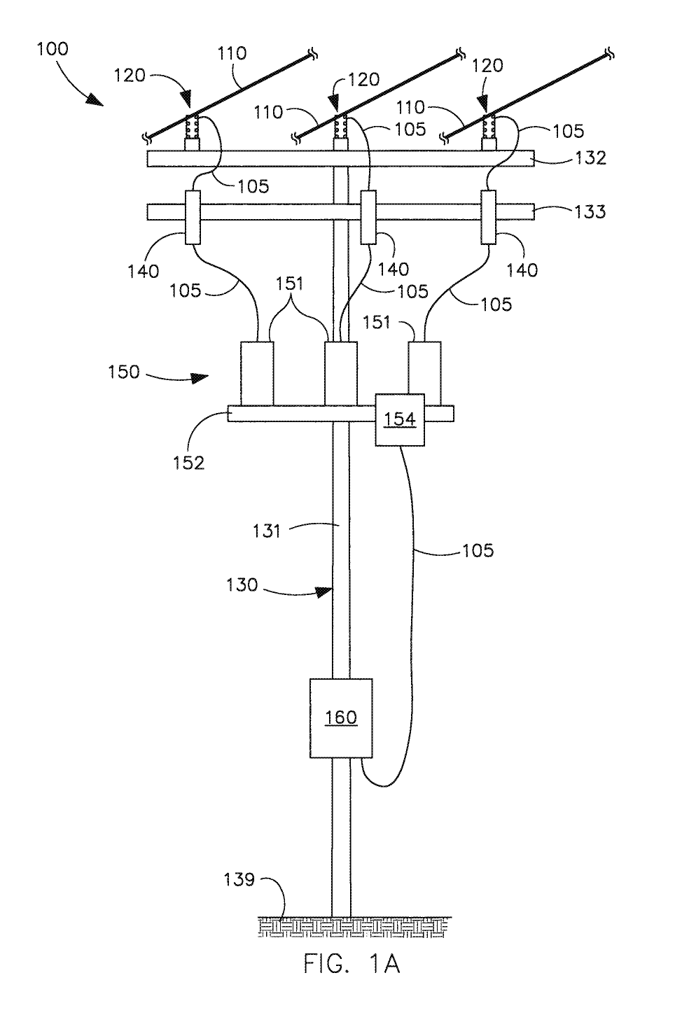

FIGS. 1A and 1B show an example system 100 for validating the operation of a capacitor bank in accordance with certain example embodiments. Specifically, FIG. 1A shows device perspective view of the system 100, and FIG. 1B shows a detailed perspective view of an example sensor used in the system 100. In one or more embodiments, one or more of the components shown in FIGS. 1A and 1B may be omitted, added, repeated, and/or substituted. Accordingly, embodiments of systems for validating the operation of a capacitor bank should not be considered limited to the specific arrangements of components shown in FIGS. 1A and 1B.

Referring to FIGS. 1A and 1B, the system 100 can include one or more power lines 110, one or more sensors 120, one or more switches 140, a capacitor bank 150, a local control system 160, and a mounting frame 130. The capacitor bank 150 can include one or more capacitors 151. In this case, there are three power lines 110, three sensors 120, three switches 140, and three capacitors 151 in the capacitor bank 150. In certain example embodiments, the capacitor bank 150 can include one or more other components, including but not limited to one or more fuses and one or more clamps. Those skilled in the art will appreciate that a number of configurations using a number of components can be used for a capacitor bank, and that the configuration of the capacitor bank 150 of FIG. 1 is only one example embodiment.

Each power line 110 can be made of one or more conductors that are made from one or more of a number of electrically conductive materials. Such materials can include, but are not limited to, aluminum, copper, steel, carbon fiber, and glass fiber. The power lines 110 can be run overhead, in which case the power lines 110 are supported by transmission towers, utility poles, a mounting frame 130, and/or other types of structures. In addition, or in the alternative, the power lines 110 can be run underground. The power lines 110 can be used for distribution (e.g., between 4 kV and 69 kV) and/or transmission (e.g., 34 kV and above) of electric power. The size of a power line 110 can vary depending on the amount of power being transmitted therethrough. In addition, when there are multiple power lines 110, the spacing between power lines 110 can vary depending on the amount of power being transmitted therethrough.

In certain example embodiments, mounting frame 130 is a structure that supports one or more power lines 110 along one or more portions of the length of the power lines 110. The mounting frame 130 can also support one or more other components of the system 100. For example, in this case, the mounting frame 130 supports the switches 140, the capacitor bank 150, and the local control system 160. The mounting frame 130 can be a single piece or multiple pieces that are mechanically coupled to each other. In this case, the mounting frame 130 has multiple pieces that include a vertical pole 131 that is affixed to (e.g., driven into, mounted to) the ground 139. One or more components (e.g., the capacitor bank 150, the local control system 160) of the system 100 can be mounted to (mechanically coupled to) the vertical pole 131. The mounting frame 130 can include one or more other features and/or take on one or more other forms. For example, a mounting frame can be, or be positioned within, an underground vault. As another example, a mounting frame can be, or be mounted atop, a ground-mounted concrete pad.

The mounting frame 130 in this case also includes a top cross support member 132 that is coupled to a top end of the vertical pole 131. One or more components (e.g., the sensors 120, the power lines 110) of the system 100 can be mounted to (mechanically coupled to) the top cross support member 132. The mounting frame 130 can also include a bottom cross support member 133 that is coupled to the top end of the vertical pole 131. In this case, the bottom cross support member 133 is positioned below, and substantially parallel to, the top cross support member 132. One or more components (e.g., the switches 140) of the system 100 can be mounted to (mechanically coupled to) the bottom cross support member 133. The mounting frame 130 can be made of one or more of a number of materials, including but not limited to steel, aluminum, and wood.

In certain example embodiments, each sensor 120 is coupled to one or more power lines 110. A sensor 120 can be coupled to a power line 110 in one or more of a number of ways, including but not limited to mechanically, electrically, and operatively. For example, if the sensor 120 includes a current transformer (CT) 121, then the sensor 120 can be operatively coupled to the power line 110, which runs through the gap formed by the CT 121. Specifically, when AC power flows through the power line 110, the power line 110 emits a magnetic field that induces a current in the CT 121. In certain exemplary embodiments, the CT 121 includes a primary winding and a secondary winding. The primary winding and the secondary winding typically have a known ratio (e.g., 4000:5). As a result, when the CT 121 surrounds a power line 110, the secondary winding generates a representation of the power flowing through the power line 110.

The CT 121 of a sensor 120 can alternatively be a voltage transformer or any other type of instrument transformer that can be used to measure an accurate proportion of an amount of power flowing through the power line 110. When a sensor 120 is operatively coupled to a power line 110, whether by CT 121, a different type of instrument transformer, or using some other operative coupling means, the sensor 120 can measure a representation of the power flowing through the power line 110. The representation can be a voltage, a current, in VARs, a phase shift, a voltage rise, or some other measure of electric power.

As stated above, the sensor 120 can be mechanically coupled to a power line 110. In such a case, a sensor 120 can include one or more coupling features 123 that are used to couple the sensor 120 to the power line 110. Such coupling features 123 can include, but are not limited to, a fastening device (e.g., a bolt, a nut), a clamp, a brace, and a collar.

The sensor 120 can also include a communication portion 124 that allows the sensor 120 to send and/or receive power and/or communication signals with one or more other components of the system 100. The communication portion 124 can send and/or receive signals using wired and/or wireless technology. For example, in FIGS. 1A and 1B, the sensor 120 can receive power induced by the CT 121 from the power flowing through the power line 110, and communication signals can be sent wirelessly between the communication portion 124 of the sensor and the local control system 160.

The sensor 120 can be a stand-alone device. Alternatively, a sensor 120 can be part of another device. For example, a sensor 120 can be part of a recloser. As another example, a sensor 120 can be part of a meter or protective relay. The sensor 120 can be located proximate to, or remotely from, a power line 110. A sensor 120 measures a representation of the power flowing through a power line 110 continuously or discretely (based on, for example, a command received from the local control system 160 or the occurrence of some event (e.g., lapse of time)).

A cable 105 can be one or more conductors that are made of one or more of a number of electrically conductive materials. A cable 105 can optionally include an insulating jacket made of one or more of a number of electrically non-conductive materials that encases each and/or all of the conductors in the cable 105. A cable 105 shown in FIG. 1A can be the same (e.g., number of conductors, size of conductor) as and/or different than the other cables 105 in the system 100.

In certain example embodiments, the capacitor bank 150 includes at least one capacitor 151 and associated components (e.g., junction box 154, capacitor bank switch 140) that are electrically coupled to form an electric circuit. For example, the Institute of Electrical and Electronics Engineers (IEEE) Standard 18 defines a capacitor bank as an assembly at one location of capacitors and all necessary accessories, such as switching equipment, protective equipment, and controls. A capacitor bank 150 can include, in addition to capacitors 151, other electrical devices. Such other electrical devices can include, but are not limited to, arresters, fuses, transformers, reactors, cables 105, controls, relays, communication equipment, and switches 1403. As with the power lines 110, to reduce the risk of an adverse electrical condition forming between components and/or phases, a minimum amount of space can separate the various components and/or phases of a capacitor bank 150.

The capacitor bank 150 can include one or more switches 140. The one or more switches 140 of the capacitor bank 150 can be used to open or close the circuit (in other words, prevent power from flowing or allow power to flow, respectively) between a power line 110 and one or more capacitors 151 (and/or other components) in the capacitor bank 150. Specifically, when a switch 140 is in an open position, there is no electric continuity between the top part of the switch 140 and the bottom part of the switch 140. When a switch 140 is in a closed position, there is electric continuity between the top part of the switch 140 and the bottom part of the switch 140.

The switch 140 can be one or more of a number of switches. For example, if the switch 140 is only a single switch, that switch can control the flow of power to all capacitors 151 in the capacitor bank 150. As another example, the switch 140 can include the same number of switches as there are capacitors 151 in the capacitor bank 150, where each of the switches 140 can be independently operated and can control one of the capacitors 151 in the capacitor bank 150. A switch 140 can change state (e.g., open to closed, closed to open) for one or more of a number of reasons. For example a switch 140 can change from closed to open to cut off power if one or more components of the capacitor bank 150 fails (e.g., if a fuse blows). As another example, a switch 140 can change from open to closed to allow power to flow to the capacitor bank 150.

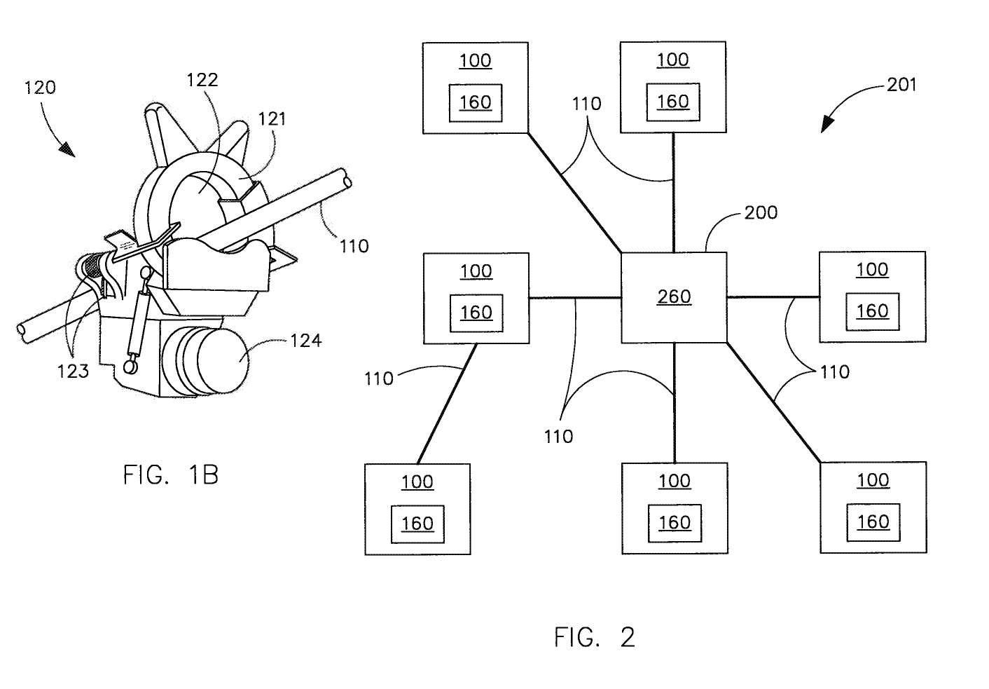

In this example, the top part of the switch 140 is electrically coupled to a power line 110, and the bottom part of the switch 140 is electrically coupled to a capacitor 151 in the capacitor bank 150. Thus, when a switch 140 is in a closed position, an electrical connection is made between the power line 110 and one or more capacitors 151 in the capacitor bank 150, allowing the one or more capacitors 151 to charge and/or discharge. In other words, when a switch 140 is closed, a capacitor 151 becomes electrically coupled to the power line 110. When a switch 140 is in an open position, the electrical connection between the power line 110 and the capacitor 151 of the capacitor bank 150 is broken, preventing the capacitor 151 from charging and/or discharging. A switch 140 can change between an open position and a closed position manually (as by, for example, a user) and/or automatically (as by, for example, a control switch, a relay operation, a command received from the local control system 160 and/or a master controller 260 (described below with respect to FIG. 2), or the occurrence of some event (e.g., lapse of time)).

A switch 140 can be mechanical and/or electronic. A switch 140 can be electrically coupled to the power line 110 and/or the capacitor bank 150 using wired or wireless technology. For example, in FIG. 1A, the top end of each switch 140 is electrically coupled to a power line 110 using a cable 105, and the bottom end of each switch 140 is electrically coupled to a capacitor 151 of the capacitor bank 150 using a different cable 105.

The junction box 154 of the capacitor bank 150 can be electrically coupled to the local control system 160 and/or one or more capacitor 151 using wired (e.g., cable 105) and/or wireless technology. If the local control system 160 is disposed within a sensor 120, the junction box 154 can be electrically and/or communicably coupled to the sensor 120. One or more components of the capacitor bank 150 can be mounted to a mounting platform 152, which can be mechanically coupled to one or more portions (e.g., vertical pole 131) of the mounting frame 130.

In certain example embodiments, the local control system 160 is communicably coupled to the communication portion 124 of one or more sensors 120. The local control system 160 can be communicably coupled to a sensor 120 using one or more cables 105 and/or using wireless technology. The coupling between the local control system 160 and the one or more sensors 120 allows for data and/or instructions to be sent between the local control system 160 and the one or more sensors 120. For example, the local control system 160 can receive one or more representations of the power flowing through a power line 110 from a sensor 120. Using these representations of the power flowing through a power line 110, the local control system 160 can validate the operation of one or more capacitors 151 without monitoring the switch 140 of the capacitor bank 150.

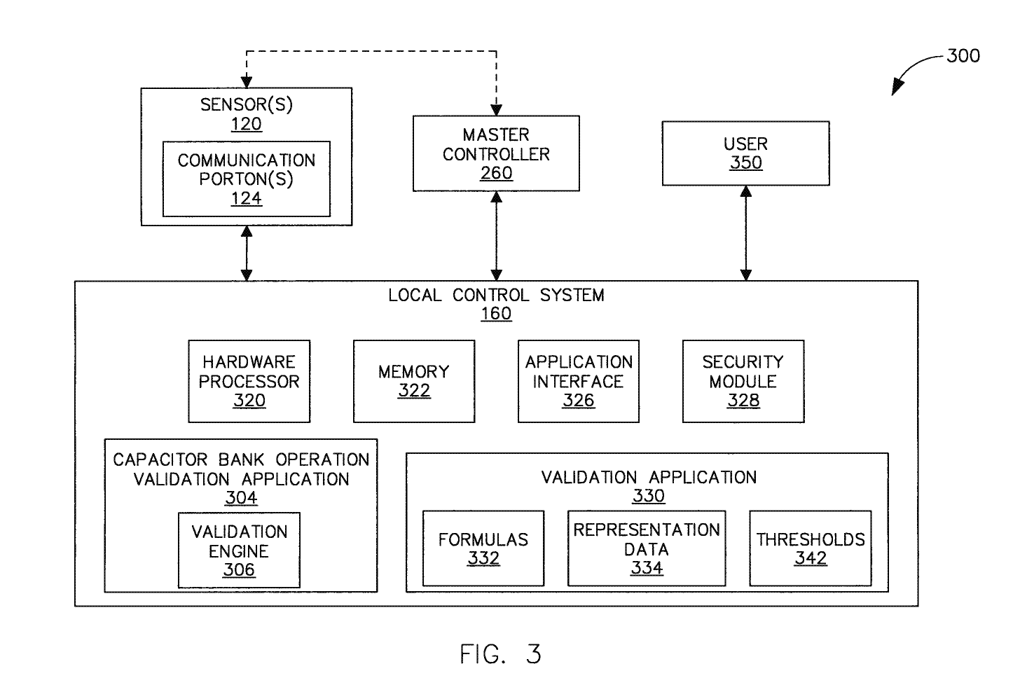

The local control system 160 can be a separate unit, as shown in FIG. 1A. For example, the local control system 160 can have its own housing and be mounted on the vertical pole 131 of the mounting frame 130. Alternatively, the local control system 160 can be part of another device, which may be in the system 100 or outside the system 100. For example, the local control system 160 can be housed within one or more sensors 120. In such a case, each sensor 120 can have its own local control system 160. As another example, the local control system 160 can be housed within one or more switches 140. More details about the local control system 160, according to certain example embodiments, can be found with respect to FIG. 3 below.

The local control system 160 can communicate with other devices, aside from one or more sensors 120, either within or outside the system 100. For example, as shown in FIG. 2, a local control system 160 can be communicably coupled to a master controller 260 in accordance with certain example embodiments. Specifically, FIG. 2 shows a system 201 that includes a number of local systems 100 as shown in FIGS. 1A and 1B that are connected to a master system 200 in accordance with certain example embodiments. In one or more embodiments, one or more of the components shown in FIG. 2 may be omitted, added, repeated, and/or substituted. Accordingly, embodiments of systems for validating the operation of a capacitor bank should not be considered limited to the specific arrangements of components shown in FIG. 2.

Referring to FIGS. 1A-2, one or more local systems 100 (in this case, there are 7 local systems 100) can be fed from (at least electrically coupled to) a master system 200 through one or more power lines 110. As shown in FIG. 2, the local systems 100 can be electrically coupled to the master system 200 radially and/or serially. While particular configurations can vary, each local system 100 can include a capacitor bank 150, one or more example sensors 120, and a local control system 160. In certain example embodiments, the master system 200 includes a master controller 260 that communicates with the local control system 160 of each local system 100. The master controller 260 and the local control systems 160 can be communicably coupled using wired (e.g., sending signals through the power lines 110) and/or wireless technology.

The master controller 260 can also be communicably coupled to one or more other components of a local system 100. Such other components can include, but are not limited to, one or more switches 140, and one or more sensors 120. In this way, the master controller 260 can be used to control an entire (or a portion of an) electric distribution and/or transmission system. Part of the function of the master controller 260 can include controlling VARs, voltage, current, and/or power flow in one or more parts of the system 201. In such a case, confirmation of the proper operation of each capacitor 151 in each capacitor bank 150 in the system 201, using example embodiments described herein, can be useful to the master controller 260.

The master controller 260 can send commands to one or more capacitor banks 150 and/or one or more local control systems 160 in the master system 200. Such commands can be to change the state of one or more capacitors 151 in a capacitor bank 150 for one or more local systems 100, to receive the status of one or more capacitors 151 in a capacitor bank 150 for one or more local systems 100, to repeat a command to change the status of one or more capacitors 151 in a capacitor bank 150 for one or more local systems 100, or to perform some other function. In certain example embodiments, the master controller 260 can be a local control system for a locally-located capacitor bank 150, as well as a master controller 260 to which the other local control systems 160 within the master system 200 receive commands and/or to which the other components (e.g., a capacitor bank 150) of the local systems 100 receive commands.

FIG. 3 shows a diagram of a system 300 in accordance with one or more example embodiments. The system 300 can be part of the system 100 described above with respect to FIGS. 1A and 1B. The system 100 can include a local control system 160, a number of sensors 120, the master controller 260, and a user 350. The local control system 160 includes a capacitor bank operation validation application 304, a storage repository 330, a hardware processor 320, a memory 322, an application interface 326, and, optionally, a security module 328. The capacitor bank operation validation application 304 can include a validation engine 306. The storage repository 330 can include formulas 332, representation data 334, and thresholds 342. In certain example embodiments, the storage repository 330 can include one or more other data elements. For example, the storage repository 330 can include records (e.g., prior notifications and/or operation of the capacitor bank 150)

Each of these components is described in further detail below. Example embodiments are not limited to the configuration shown in FIG. 3 and discussed herein. Additionally, although certain components have been enumerated as being part of the system 300, it is understood that some components are combined with other components and/or some components are further divided into additional components in other alternative example embodiments.

In one or more example embodiments, the local control system 160 is implemented according to a client-server topology. The local control system 160 may correspond to enterprise software running on one or more servers, and in some embodiments may be implemented as a peer-to-peer system, or resident upon a single computing system. In addition, the local control system 160 may be accessible from other machines using one or more application programming interfaces and/or user interfaces. In one or more example embodiments, the local control system 160 may be accessible over a network connection (not shown), such as the Internet, by one or more users 350. Further, information and/or services provided by the local control system 160 may also be stored and accessed over the network connection.

Alternatively or additionally, in one or more example embodiments, the local control system 160 is a local computer system of the user 350 and/or of one or more sensors 120. In such embodiments, the local control system 160 is, optionally, not implemented using a client-server topology. For example, the local control system 160 corresponds to a laptop computer, desktop computer, mobile device, another type of computing device, or a combination of multiple computing devices. Additionally or alternatively, the local control system 160 is a distributed computer system and/or a multi-processor computer system in which the computer system includes multiple distinct computing devices.

Continuing with FIG. 3, a user 350 as described herein may be any person that is involved with the removal, installation, operation, and/or maintenance of capacitor banks and/or other electrical devices in an electric transmission and/or distribution system. Examples of a user may include, but are not limited to, a company representative, an electrician, an engineer, a mechanic, an operator (local or remote), a consultant, a contractor, and a manufacturer's representative. A user 350 can interact with a capacitor bank 150 directly or remotely.

The user 350 uses one or more applications to communicate with the local control system 160 and/or the master controller 260 in accordance with one or more example embodiments. For example, the user 350 receives a notification from the local control system 160 and/or the master controller 260 as to the operation or lack of operation of a particular capacitor 151 in a capacitor bank 150 for a particular local system 100. According to some example embodiments, the user 350 sends information (e.g., user preferences, settings, data) to the local control system 160 and/or the master controller 260 in a number of manners (e.g., modes of communication), including but not limited to a direct input, over the Internet, some other suitable mode for sending information, or any combination thereof.

In certain example embodiments, the information sent by the user 350 to the local control system 160 and/or the master controller 260 is delivered automatically (e.g., according to a default setting, a consumer preference, an occurrence of an event) or on demand, for example, in response to a notice from the local control system 160 and/or the master controller 260. The local control system 160 and/or the master controller 260 interacts with the user 350 in the same manner that the user 350 interacts with the local control system 160 and/or the master controller 260, or in a different manner using different modes of communication. The user 350 uses a user system (not shown), which is discussed below in further detail, to interact with the local control system 160 and/or the master controller 260 using software (not shown) in accordance with one or more example embodiments.

In one or more example embodiments, the user 350 interacts with one or more sensors 120. Specifically and according to some example embodiments, the user 350 can send information (e.g., settings) to and receive information (e.g., representations 334 (e.g., voltage, current) of the power flowing through a power line 110) from one or more sensors 120.

In one or more example embodiments, the user 350 sends information to the sensors 120 in a number of manners (e.g., modes of communication), including but not limited to a direct input, over the Internet, some other suitable mode for sending information, or any combination thereof. Further, the user 350 receives information from the sensors 120 in some example embodiments. The information is delivered automatically (e.g., according to a default setting, a consumer preference, an occurrence of an event) or on demand, for example, in response to a request from the sensors 120. In certain example embodiments, the sensor 120 interacts with the user 350 in the same manner that the user 350 interacts with the sensors 120, or in a different manner using different modes of communication. The user 350 uses the user system (not shown), which is described below in further detail, to interact with the sensors 120 using software (not shown) in accordance with one or more example embodiments.

In one or more example embodiments, each sensor 120 sends information (e.g., representations 334) to, and receives information (e.g., a request for a representation) from, the local control system 160. The information is delivered automatically (e.g., according to a default setting, a marketing entity preference, an occurrence of an event) or on demand, as from a request made by the local control system 160. The data provided by the sensors 120 can include, but is not limited to, the status of a capacitor 151 in a capacitor bank 150, a representation 334 of the power flowing through a power line 110, and a change in the status of a capacitor 151 in a capacitor bank 150.

Each sensor 120 interacts with the local control system 160 in the same mode of communication that the local control system 160 interacts with the sensor 120 or using different modes of communication in alternative example embodiments. In one or more example embodiments, each sensor 120 uses a sensor system (not shown) to interact with the local control system 160 using sensor software (not shown), which is discussed in further detail below. In certain example embodiments, a sensor 120 can interact with the master controller 260 in addition to, or instead of, the local control system 160. The local control system 160 also can be implemented as a browser extension according to some example embodiments. In such a scenario, user software and/or sensor software interacts directly with the local control system 160 as a browser extension.

Continuing with FIG. 3, the local control system 160 interacts with the user 350, the master controller 260, and/or each sensor 120 using an application interface 326 in accordance with one or more example embodiments. Specifically, the application interface 326 of the local control system 160 receives input from and sends output to the user 350, the master controller 260, and/or each sensor 120. The user 350, the master controller 260, and/or each sensor 120 includes an interface to receive data from and send data to the local control system 160 in certain example embodiments. Examples of this interface include, but are not limited to, a graphical user interface, an application programming interface, a keyboard, a monitor, a mouse, a web service, a data protocol adapter, some other hardware and/or software, or any suitable combination thereof.

In one or more embodiments of the invention, the information received by the application interface 326 can include, but is not limited to, operational data, user preferences, commands, settings, and feedback. The information sent by the application interface 326 can include, but is not limited to, a request for data representation 334, a notification, and a request for additional information. The information sent by the application interface 326 specifies, but is not limited to, a user 350, a master controller 260, a sensor 120, a Uniform Resource Identifier (URI) (e.g., a Uniform Resource Locator (URL), a web address, etc.), data identified by and/or requested by the validation engine 306, some other software or source of information, or any suitable combination thereof.

In one or more embodiments of the invention, the information (i.e., data) transferred among the application interface 326, the user 350, the master controller 260, and/or each sensor 120 corresponds to metadata associated with such information. In this case, the metadata describes the data specified (i.e., the metadata provides context for the specified data). In one or more embodiments of the invention, the local control system 160 and/or the master controller 260 supports various data formats provided by the user 350 and/or each sensor 120.

Continuing with FIG. 3, the local control system 160 and/or the master controller 260 retrieves and stores formulas 332, representation data 334, and thresholds 342. More specifically, the local control system 160 and/or the master controller 260 uses the validation engine 306 to retrieve and store formulas 332, representation data 334, and thresholds 342 in the storage repository 330 in accordance with one or more example embodiments.

In one or more example embodiments, a formula 332 includes an equation, set of parameters, or other means of using quantitative data to reach a numerical result. The formulas 332 of the storage repository 330 can include one or more formulas. Each formula is fixed in certain example embodiments, or is adjusted based on recent trends, user input, and/or any other information that affects the result produced by the formula in other example embodiments. A formula can use one or more representations 334 measured by a sensor 120 according to certain example embodiments. An example of three such formulas 332 can include, but is not limited to:

$$\begin{matrix}{φ}_{A} Δ K VAR \% = \frac{\vert {φ}_{A} Δ K VAR \vert}{\frac{1}{3} ( Cap Bank Size )} * 100 , & ( 1 ) \\ {φ}_{B} Δ K VAR \% = \frac{\vert {φ}_{B} Δ K VAR \vert}{\frac{1}{3} ( Cap Bank Size )} * 100 , and & ( 2 ) \\ {φ}_{C} Δ K VAR \% = \frac{\vert {φ}_{C} Δ K VAR \vert}{\frac{1}{3} ( Cap Bank Size )} * 100 , & ( 3 )\end{matrix}$$

where Cap Bank Size is the rating of the capacitor bank 150 in kVARs, and ΦΔKVAR % is the % change in KVAR of a particular power line 110.

In one or more example embodiments, the representation data 334 of the storage repository 330 is based on actual and/or measured data measured by a sensor 120. Some or all representation data 334 measured by a sensor 120 can be stored in the storage repository 330. For example, only the previous 24 hours of representation data 334 may be stored in the storage repository 330. Each representation 334 measured by a sensor 120 can be associated with a time. Time in this case can be a clock time, an interval of time, or some other measure of time. Thus, when a representation 334 is stored in the storage repository 330, the representation 334 can be associated with a particular sensor 120 and with a particular time. In this way, the local control system 160 can measure the current state of one or more capacitors 151 in a capacitor bank 150 and/or whether the one or more capacitors 151 in the capacitor bank 150 has changed state compared to a representation measured by a sensor 120 at some prior point in time.

In one or more example embodiments, the thresholds 342 of the storage repository 330 are a measure of one or more of a number of data points and/or parameters. Specifically, the thresholds 342 represent values or ranges of values that measure the state (or change in state) of a capacitor 151 of a capacitor bank 150. The thresholds 342 can be in terms of voltage, current, VARs, phase, a change in voltage, a change in current, a change in VARs, a phase shift, and/or any other appropriate measure of the state and/or performance of one or more capacitors 151.

A number of different thresholds 342 can be stored in the storage repository 330. Examples of different thresholds 342 can include, but are not limited to, voltage thresholds, current thresholds, VAR thresholds, and count thresholds. Each threshold 342 can be a single number, a range of numbers, a word, and/or some other suitable measure depending upon the example embodiment. Each threshold 342 is fixed according to some example embodiments, while in other example embodiments, each threshold 342 varies based on one or more of a number of factors, including but not limited to user input, operational history, ambient temperature, and capacitor size.

Continuing with FIGS. 1A-3, the storage repository 330 is a persistent storage device (or set of devices) that stores software and data used to assist the validation engine 306 in determining whether a capacitor bank has operated. In one or more example embodiments, the storage repository 330 stores the formulas 332, representation data 334, and thresholds 342. Examples of a storage repository 330 include, but are not limited to, a database (or a number of databases), a file system, a hard drive, some other form of data storage, or any suitable combination thereof. The storage repository 330 is located on multiple physical machines, each storing all or a portion of the formulas 332, representation data 334, and thresholds 342 according to some example embodiments. Each storage unit or device is physically located in the same or different geographic location.

The storage repository 330 is operatively connected to the capacitor bank operation validation application 304. In one or more example embodiments, the capacitor bank operation validation application 304 includes functionality to determine whether a capacitor bank has operated. More specifically, the capacitor bank operation validation application 304 sends information to and/or receives information from the storage repository 330 in order to determine whether a capacitor bank has operated. The functions of the capacitor bank operation validation application 304 can be performed on a single computing device or on multiple computing devices (for example, on different sensors 120). When the functions of the capacitor bank operation validation application 304 are performed on multiple computing devices, a number of configurations and/or frameworks are used in certain example embodiments. The configurations and/or software frameworks are designed to work with multiple data nodes and large quantities of data. One or more calculations performed by one or more components of the capacitor bank operation validation application 304 are performed on multiple machines operating in parallel, where the results from each machine is combined to generate a result to the one or more calculations.

Each component of the capacitor bank operation validation application 304 described herein (specifically, the validation engine 306) uses one or more algorithms (e.g., formulas 332) to perform one or more calculations. Each algorithm is designed to receive specific types of data (e.g., representations 334) and generate one or more specific results using such data. A specific result can be a word, a phrase, a number, a range of numbers, a rating, and/or some other suitable output according to some example embodiments. Each algorithm can be fixed, variable, self-adjusting, or otherwise changed. Each algorithm can use one or more pieces of data from one or more sensors 120 and/or the master controller 260.

In one or more embodiments of the invention, the validation engine 306 of the capacitor bank operation validation application 304 coordinates the storage repository 330 and, optionally, the security module 328. Specifically, the validation engine 306 coordinates the transfer of information between the application interface 326 and the storage repository 330 according to certain example embodiments.

Further, the validation engine 306 also retrieves the formulas 332, the representation data 334, and the thresholds 342 from, and sends the formulas 332, the representation data 334, and the thresholds 342 to the storage repository 330 for use by the validation engine 306. The validation engine 306 also retrieves the formulas 332, the representation data 334 and the thresholds 342 from the storage repository 330 to be sent to the user 350, the master controller 260, and/or one or more sensors 120.

Continuing with FIGS. 1A-3, the validation engine 306 retrieves, in example embodiments, information (e.g., representations 334, commands) from the data repository 330, the master controller 260, and/or one or more specific sensors 120. Alternatively, the validation engine 306 queries all sensors 120, the master controller 260, and the storage repository 330 for any information needed.

In certain example embodiments, the validation engine 306 receives data (e.g., representations 334) from the one or more sensors 120. The validation engine 306 can also send a request for data to the one or more sensors 120 in certain example embodiments. A request can be for a specific type of data (e.g., a voltage representation, a current representation) and/or at a specific time in some example embodiments. A request can also be sent to a specific sensor 120 according to some example embodiments. A request can be sent to one or more sensors 120 based on one or more of a number of events, including but not limited to passage of time, a command sent by the mater controller 260 to a capacitor bank 150, and/or a need identified by the validation engine 306. Any request sent and/or data received by the validation engine 306 is executed using the application interface 326.

In certain example embodiments, the validation engine 306 also sends data (e.g., notifications) to, and receives data (e.g., commands) from the master controller 260. The data received from the master controller can include a command sent by the master controller 260 to the capacitor bank 150. Such a command can be, for example, to direct one or more capacitors 151 of the capacitor bank 150 to change from one state (e.g., discharge) to another state (e.g., charge). As another example, a command can be for the switch 152 to change from one state (e.g., close) to another state (e.g., open). Such a command sent by the master controller 260 can be sent to the capacitor bank 150, which relays the command to the local control system 160. Alternatively, such a command sent by the master controller 260 can be sent to both the capacitor bank 150 and the local control system 160. As yet another alternative, the command sent by the master controller 260 can be received by the local control system 160, which then forwards the command to the capacitor bank 150.

When the validation engine 306 sends data to the master controller 260 (and in some cases the user 350), the data can include a notification. In such a case, the notification can notify the master controller 260 the status of one or more capacitors 151 in a capacitor bank 150. A notification sent by the validation engine 306 to the master controller 260 can be in response to some event (e.g., a command sent by the master controller 260, the passage of time, a change in a representation 334 of the power flowing through a power line 110) or can be sent randomly. The status of a capacitor 151 can include, but is not limited to, failure, changed state, charging, and/or discharging.

The validation engine 306 also determines the state of one or more capacitors 151 in a capacitor bank 150. The validation engine 306 can determine the state of a capacitor 151 using a representation 334 received from a sensor 120 and a formula 332 received from the storage repository 330. The status of a capacitor 151 can be a discrete observation (the current state of the capacitor 151) and/or relative to something (e.g., relative to a state of the capacitor 151 at a prior time, relative to an expected state of the capacitor 151 at the current time).

The validation engine 306 can also include a counter. In such a case, if an initially unsuccessful operation of a capacitor 151 occurs, the validation engine 306 can track the number of times an attempt has been made to retry the same operation. In addition, or in the alternative, the timer function of the validation engine 306 can track an amount of time between events.

Continuing with FIGS. 1A-3, the hardware processor 320 within the local control system 160 executes software in accordance with one or more embodiments of the invention. Specifically, the hardware processor 320 executes the local control system 160 or any of the engines and repositories described above and shown in FIG. 3, as well as software used by the user 350, the master controller, and/or one or more sensors 120. The hardware processor 320 can be an integrated circuit, a central processing unit, a multi-core processing chip, a multi-chip module including multiple multi-core processing chips, or other hardware processor in one or more example embodiments. The hardware processor 320 is known by other names, including but not limited to a computer processor, a microprocessor, and a multi-core processor. In one or more example embodiments, the hardware processor 320 executes software instructions stored in memory 322. The memory 322 includes one or more cache memories, main memory, and/or any other suitable type of memory. The memory 322 is discretely located on the local control system 160 relative to the hardware processor 320 according to some example embodiments. In certain configurations, the memory 322 also is integrated with the hardware processor 320.

Optionally, in one or more example embodiments, the security module 328 secures interactions between the local control system 160, the master controller, the user 350 and/or the sensors 120. More specifically, the security module 328 authenticates communication from software based on security keys verifying the identity of the source of the communication. For example, user software may be associated with a security key enabling the user software to interact with the local control system 160 and/or the master controller 260. Further, the security module 328 restricts receipt of information, requests for information, and/or access to information in some example embodiments.

The user software can interact with the local control system 160, the sensors 120, and/or the master controller 260 using a browser extension. In this case, the browser extension maintains an active session with the local control system 160, the sensors 120, and/or the master controller 260 after the security module 328 has authenticated the user software. For example, the browser extension continues to interact with the local control system 160 as the user 350 views various web content in the user software. In this example, the browser extension receives notifications from the local control system 160 for presenting to the user 350.

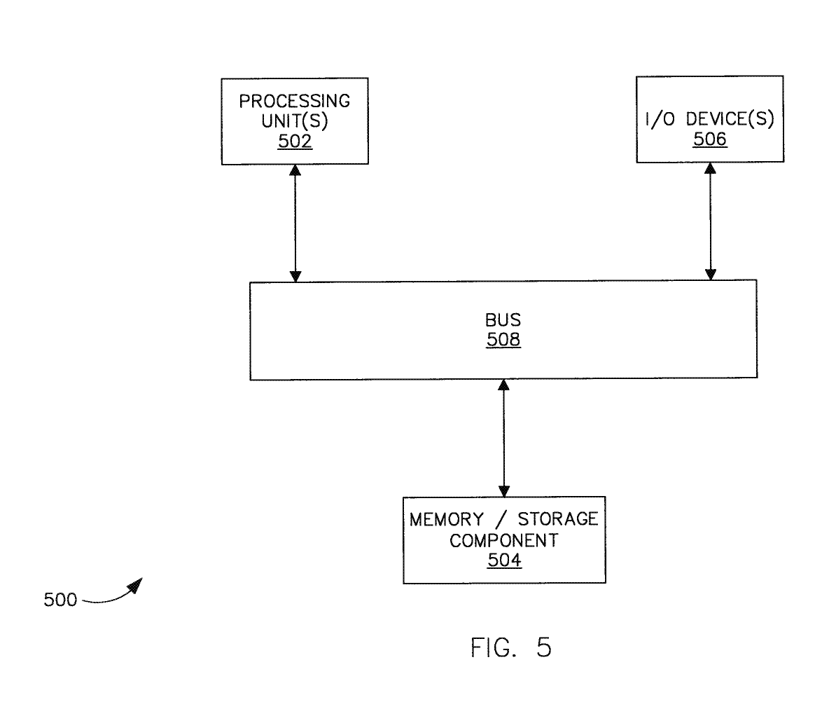

As discussed above, the user 350, sensors 120, local control system 160, and master controller 260 can use their own system or share a system in certain example embodiments. Such a system can be, or contain a form of, an Internet-based or an intranet-based computer system that is capable of communicating with the applicant software. A computer system includes any type of computing device and/or communication device, including but not limited to the local control system 160. Examples of such a system can include, but are not limited to, a desktop computer with Internet or intranet access, a laptop computer with Internet or intranet access, a smart phone, a server, a server farm, and a personal digital assistant (PDA). Such a system can correspond to a computer system as described below with regard to FIG. 5.

Further, as discussed above, such a system can have corresponding software (e.g., user software and sensor software). The software can execute on the same or a separate device (e.g., a server, mainframe, desktop personal computer (PC), laptop, personal desktop assistant (PDA), television, cable box, satellite box, kiosk, telephone, mobile phone, or other computing devices) and can be coupled by a network (e.g., Internet, Intranet, Extranet, Local Area Network (LAN), Wide Area Network (WAN), or other network communication methods), with wire and/or wireless segments according to some example embodiments. The software of one system can be a part of, or operate separately but in conjunction with, the software of another system within the system 300.

In certain example embodiments, the local control system 160 does not include a hardware processor 320. In such a case, the local control system 160 can include, as an example, one or more field programmable gate arrays (FPGA). Using FPGAs and/or other similar devices known in the art allows the local control system 160 to be programmable and function according to certain formulas and thresholds without the use of a hardware processor.

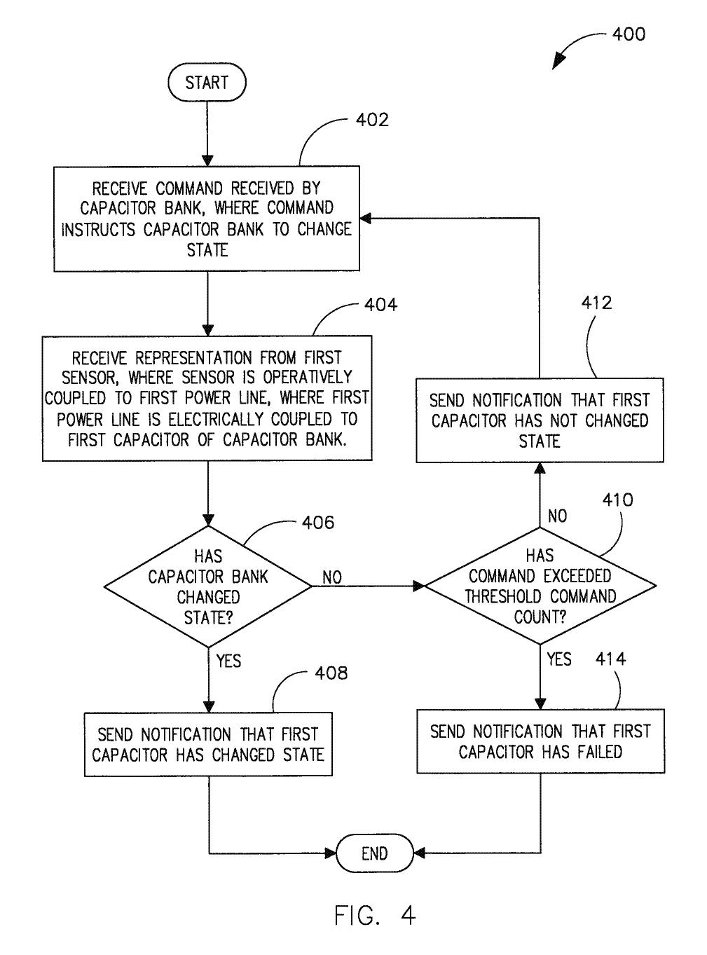

FIG. 4 is a flow chart presenting a method 400 for validating an operation of a capacitor bank in accordance with certain example embodiments. While the various steps in this flowchart are presented and described sequentially, one of ordinary skill will appreciate that some or all of the steps may be executed in different orders, may be combined or omitted, and some or all of the steps may be executed in parallel. Further, in one or more of the example embodiments, one or more of the steps described below may be omitted, repeated, and/or performed in a different order.

In addition, a person of ordinary skill in the art will appreciate that additional steps not shown in FIG. 4 may be included in performing this method. Accordingly, the specific arrangement of steps should not be construed as limiting the scope. Further, a particular computing device, as described, for example, in FIG. 5 below, can be used to perform one or more of the steps for the method 400 described below in certain exemplary embodiments. As defined herein, the state (also called the operation) of a capacitor bank 150 can be the state of one or more capacitors 151 and/or the switch 140 of a capacitor bank 150 and/or the state or status of one or more components (e.g., a fuse, a clamp, a switch 140) of the capacitor bank 150. The operation of a capacitor bank 150 can be the current status of one or more capacitors 151 (and/or some other component (e.g., a switch 140)) of the capacitor bank 150, a change in status one or more capacitors 151 (and/or some other component) of the capacitor bank 150, the successful operation of one or more components of the capacitor bank 150, the failed operation of one or more components of the capacitor bank 150, and/or any other condition or status associated with the capacitor bank 150, The operation of a capacitor bank 150 can be determined, directly or indirectly, based on one or more representations 334 of the power flowing through a power line 110 using example embodiments.

In some cases, example embodiments can be used in conjunction with known technology to determine operational status and/or problems of a specific component of a capacitor bank 150. For example, identification of a specific failure of a component of a capacitor bank 150 can be determined by using example embodiments in conjunction with a neutral current sensor that monitors a neutral line of a capacitor bank 150. In such a case, existing technologies used without example embodiments cannot determine the status of a capacitor bank or a specific component within a capacitor bank.

Referring now to FIGS. 1A-4, the example method 400 begins at the START step and proceeds to step 402, where a command received by a capacitor bank 150 is received. The command can be received by the local control system 160. The command can instruct the capacitor bank 150 to change state. In certain example embodiments, the command is sent by the master controller 260. The command can be for one or more capacitors 151 in a capacitor bank 150 to change state. In response to the command, one or more components (e.g., the switch 140) of the capacitor bank 150 operates in compliance with the command. In some cases, no such command is received.

In step 404, a representation 334 is received from a sensor 120. In certain example embodiments, the sensor 120 is operatively coupled to a power line 110. In turn, the power line 110 is electrically coupled to one or more capacitors 151 of the capacitor bank 150. The representation 334 can be received by the local control system 160. The representation 334 can be received from the sensor by the local control system 160 based on the command. Alternatively, the representation 334 can be received from the sensor by the local control system 160 randomly or based on the occurrence of some other event. The sensor can measure the representation 334 continuously, randomly, based on an instruction received from the local control system 160, and/or based on some other event.

If no command was received (as in step 402 above), then the representation 334 can be received from the sensor 120 based on a request sent by the local control system 160, based on the passage of time, or based on some other event. In such a case, the local control system 160 can determine the state of the capacitor bank 150 and send a notification to the master controller 260, at which point the process proceeds to the END step.

In step 406, once the representation 334 is received, a determination is made as to whether the capacitor bank 150 (or, more specifically, one or more capacitors 151 in the capacitor bank 150) has changed state. In certain example embodiments, the determination is made by the local control system 160. For this determination to be made, the local control system 160 can compare the current state of the capacitor bank 150 with a previous state of the capacitor bank 150. The previous state of the capacitor bank 150 can be based on the representation 334 of the power line 110 taken at a previous time. In any case, using the representation 334 and one or more formulas 332, the local control system 160 can determine a current state of the capacitor bank 150.

If a prior representation 334 is available, the local control system 160 can also determine whether the capacitor bank 150 has changed states. If the capacitor bank 150 has changed state, the process proceeds to step 408. If the capacitor bank 150 has not changed state, the process proceeds to step 410.

In step 408, a notification is sent that the capacitor bank 150 has changed state. The notification can be sent by the local control system 160. In certain example embodiments, the notification can be sent to the master controller 260. In some cases, if the capacitor bank 150 has not changed state, but the command was not intended to change the state of the capacitor bank 150, the local control system 160 can send a notification to the master controller 260 that the capacitor bank 150 has not changed state. After step 408 is complete, the process can proceed to the END step.

In step 410, a determination is made as to whether the command has exceeded a threshold command count. The determination as to whether the command has exceeded a threshold command count can be made by the local control system 160. The threshold command count can be a threshold 342 stored in the storage repository 330. In certain example embodiments, one or more efforts can be made to change the state of a capacitor bank 150 when the first effort to do so is unsuccessful. In such a case, the local control system 160 can count the number of unsuccessful efforts that have been made to change the state of the capacitor bank 150. Such notification can include how many attempts have been made to change the state of the capacitor bank 150. If the command has exceeded the threshold command count, the process proceeds to step 414. If the command has not exceeded the threshold command count, the process proceeds to step 412.

In step 412, a notification that the capacitor bank 150 has not changed state is sent. The notification can be sent by the local control system 160. The notification can be received by the master controller 260. The notification can include the number of unsuccessful attempts that have been made to change to the status of the capacitor bank 150. In certain example embodiments, the notification and/or the operation of the capacitor bank is logged. In such a case, the record can be stored in the storage repository 330. Each record can be associated with a time. After step 412 is complete, the process reverts to step 402.

In step 414, a notification that the capacitor bank 150 has failed is sent. The n notification can be sent by the local control system 160. The notification can be received by the master controller 260. The notification can include the number of unsuccessful attempts that have been made to change to the status of the capacitor bank 150. After step 412 is complete, the process can proceed to the END step.

In certain example embodiments, there are no prior representations 334 of the power flowing through the power line 110 available. In addition, or in the alternative, there are no commands prompting a change in the status of the capacitor bank 150. In such a case, the local control system 160 can determine, using the representation 334 at the current time, one or more formulas 332, and/or one or more thresholds 342, the current state of the capacitor bank 150. In such a case, the local control system 160 can send a notification to the master controller 260 as to the status of the capacitor bank 150. As defined herein, the status of a capacitor bank can include the status of any one or more capacitors within the capacitor bank 150.

FIG. 5 illustrates one embodiment of a computing device 500 that implements one or more of the various techniques described herein, and which is representative, in whole or in part, of the elements described herein pursuant to certain exemplary embodiments. Computing device 500 is one example of a computing device and is not intended to suggest any limitation as to scope of use or functionality of the computing device and/or its possible architectures. Neither should computing device 500 be interpreted as having any dependency or requirement relating to any one or combination of components illustrated in the example computing device 500.

Computing device 500 includes one or more processors or processing units 502, one or more memory/storage components 504, one or more input/output (I/O) devices 506, and a bus 508 that allows the various components and devices to communicate with one another. Bus 508 represents one or more of any of several types of bus structures, including a memory bus or memory controller, a peripheral bus, an accelerated graphics port, and a processor or local bus using any of a variety of bus architectures. Bus 508 includes wired and/or wireless buses.

Memory/storage component 504 represents one or more computer storage media. Memory/storage component 504 includes volatile media (such as random access memory (RAM)) and/or nonvolatile media (such as read only memory (ROM), flash memory, optical disks, magnetic disks, and so forth). Memory/storage component 504 includes fixed media (e.g., RAM, ROM, a fixed hard drive, etc.) as well as removable media (e.g., a Flash memory drive, a removable hard drive, an optical disk, and so forth).

One or more I/O devices 506 allow a customer, utility, or other user to enter commands and information to computing device 500, and also allow information to be presented to the customer, utility, or other user and/or other components or devices. Examples of input devices include, but are not limited to, a keyboard, a cursor control device (e.g., a mouse), a microphone, and a scanner. Examples of output devices include, but are not limited to, a display device (e.g., a monitor or projector), speakers, a printer, and a network card.

Various techniques are described herein in the general context of software or program modules. Generally, software includes routines, programs, objects, components, data structures, and so forth that perform particular tasks or implement particular abstract data types. An implementation of these modules and techniques are stored on or transmitted across some form of computer readable media. Computer readable media is any available non-transitory medium or non-transitory media that is accessible by a computing device. By way of example, and not limitation, computer readable media includes “computer storage media”.

“Computer storage media” and “computer readable medium” include volatile and non-volatile, removable and non-removable media implemented in any method or technology for storage of information such as computer readable instructions, data structures, program modules, or other data. Computer storage media include, but are not limited to, computer recordable media such as RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which is used to store the desired information and which is accessible by a computer.

The computer device 500 is connected to a network (not shown) (e.g., a local area network (LAN), a wide area network (WAN) such as the Internet, or any other similar type of network) via a network interface connection (not shown) according to some exemplary embodiments. Those skilled in the art will appreciate that many different types of computer systems exist (e.g., desktop computer, a laptop computer, a personal media device, a mobile device, such as a cell phone or personal digital assistant, or any other computing system capable of executing computer readable instructions), and the aforementioned input and output means take other forms, now known or later developed, in other exemplary embodiments. Generally speaking, the computer system 500 includes at least the minimal processing, input, and/or output means necessary to practice one or more embodiments.

Further, those skilled in the art will appreciate that one or more elements of the aforementioned computer device 500 is located at a remote location and connected to the other elements over a network in certain exemplary embodiments. Further, one or more embodiments is implemented on a distributed system having one or more nodes, where each portion of the implementation (e.g., validation engine 306) is located on a different node within the distributed system. In one or more embodiments, the node corresponds to a computer system. Alternatively, the node corresponds to a processor with associated physical memory in some exemplary embodiments. The node alternatively corresponds to a processor with shared memory and/or resources in some exemplary embodiments.

Using example embodiments of validating the operation of some or all of a capacitor bank described allows a user and/or a master controller to understand, in real time, when one or more capacitors of a capacitor bank fail to operate in the manner expected. This information can be used during steady state operation of the capacitor bank and/or when the state of the capacitor bank changes. Installation of equipment (e.g., sensors) needed to validate the operation of some or all of a capacitor bank can be minimal, as existing sensors can be used in many cases. Installation of the local control system (and it corresponding functionality as described herein) may also be minimal. Specifically, if a local control system already is in place, a simple addition to existing operating parameters can be installed. If a local control system is not already in place, one can be installed seamlessly, often using wireless or a minimal amount of wired technology.

Although embodiments described herein are made with reference to example embodiments, it should be appreciated by those skilled in the art that various modifications are well within the scope and spirit of this disclosure. Those skilled in the art will appreciate that the example embodiments described herein are not limited to any specifically discussed application and that the embodiments described herein are illustrative and not restrictive. From the description of the example embodiments, equivalents of the elements shown therein will suggest themselves to those skilled in the art, and ways of constructing other embodiments using the present disclosure will suggest themselves to practitioners of the art. Therefore, the scope of the example embodiments is not limited herein.

What is claimed is:

1. A system for validating an operation of a capacitor bank, comprising:
a first capacitor of the capacitor bank electrically coupled to a first power line;
a first sensor operatively coupled to the first power line, wherein the first sensor is configured to measure a first representation of power flowing through the first power line;
a local control system communicably coupled to the first sensor, wherein the local control system receives the first representation of the power flowing through the first power line from the first sensor, wherein the local control system validates the operation of the first capacitor based on the first representation.

2. The system of claim 1, further comprising:
a second capacitor of the capacitor bank electrically coupled to a second power line;
a third capacitor of the capacitor bank electrically coupled to a third power line;
a second sensor operatively coupled to the second power line, wherein the second sensor is configured to measure a second representation of power flowing through the second power line; and
a third sensor operatively coupled to the third power line, wherein the third sensor is configured to measure a third representation of power flowing through the third power line,
wherein the local control system is further communicably coupled to the second sensor and the third sensor, wherein the local control system receives the second representation of the power flowing through the second power line from the second sensor, wherein the local control system receives the third representation of the power flowing through the third power line from the third sensor, and wherein the local control system further validates the operation of the second capacitor based on the second representation and the operation of the third capacitor based on the third representation.

3. The system of claim 1, wherein the first sensor measures the first representation of the power flowing through the first power line when the first capacitor receives a command to change from a first state to a second state.

4. The system of claim 3, wherein the first sensor sends a notification to a master controller when the first capacitor receives the command to change from the first state to the second state, but wherein the first capacitor fails to change from the first state to the second state.

5. The system of claim 4, wherein the master controller is located at a master station, and wherein the local control system is located at one of a plurality of local stations, wherein each of the plurality of local stations is electrically coupled to the master station.

6. The system of claim 1, wherein the first sensor measures the first representation of the power flowing through the first power line on a substantially continuous basis.

7. The system of claim 6, wherein the local control system sends a notification to a master controller when the first sensor detects a change in the first representation of the power flowing through the first power line.

8. The system of claim 1, wherein the local control system comprises:
a hardware processor; and
a validation engine executing on the hardware processor and:
receiving a command received by the first capacitor, wherein the command instructs the first capacitor to change from a first state to a second state;
receiving the first representation from the first sensor;
determining, based on the first representation, whether the first capacitor changes from the first state to the second state; and
sending a notification to a master controller when the first capacitor fails to change from the first state to the second state in response to the command.

9. The system of claim 1, wherein the local control system comprises:
a hardware processor; and
a validation engine executing on the hardware processor and:
receiving the first representation from the first sensor at a first time;
receiving the first representation from the first sensor at a second time;
detecting a change in the first representation between the first time and the second time; and
sending a notification to a master controller, wherein the notification comprises the change in the first representation.

10. The system of claim 1, wherein the local control system is located within a housing of the first sensor.

11. The system of claim 1, wherein the first sensor comprises a current transformer that surrounds the first power line.

12. The system of claim 1, wherein the first power line is a distribution line in an electrical distribution system.

13. A method for validating an operation of a capacitor bank, comprising:
receiving a first representation from a first sensor at a first time, wherein the first sensor is operatively coupled to a first power line, wherein the first power line is electrically coupled to a first capacitor of the capacitor bank;
determining, using a hardware processor and based on the first representation, whether the first capacitor of the capacitor bank has changed from a first state to a second state; and
sending a first notification comprising information as to whether the first capacitor of the capacitor bank has changed from the first state to the second state.

14. The method of claim 13, further comprising:
receiving, prior to receiving the first representation from the first sensor, a first command received by the first capacitor, wherein the first command instructs the first capacitor to change from the first state to the second state.

15. The method of claim 14, further comprising:
receiving, prior to receiving the first command, the first representation from the first sensor at a prior time, wherein the prior time is before the first time.

16. The method of claim 14, further comprising:
receiving, after sending the first notification, a second command received by the first capacitor, wherein the second command instructs the first capacitor to change from the first state to the second state,
wherein the first notification comprises information that the first capacitor of the capacitor bank remained in the first state after receiving the first command.

17. The method of claim 16, further comprising:
receiving, after receiving the second command, a second representation from the first sensor at a second time;
determining, using a hardware processor and based on the second representation, that the first capacitor of the capacitor bank remains in the first state;
determining that the second command exceeds a command count threshold; and
sending a second notification to the master controller, wherein the second notification comprises information that the first capacitor has failed.

18. The method of claim 13, further comprising:
receiving a second representation from a second sensor at the first time, wherein the second sensor is operatively coupled to a second power line, wherein the second power line is electrically coupled to a second capacitor of the capacitor bank;
receiving a third representation from a third sensor at the first time, wherein the third sensor is operatively coupled to a third power line, wherein the third power line is electrically coupled to a third capacitor of the capacitor bank;
determining, using a hardware processor and based on the second representation, whether the second capacitor of the capacitor bank has changed from the first state to the second state; and
determining, using a hardware processor and based on the third representation, whether the third capacitor of the capacitor bank has changed from the first state to the second state,
wherein the notification further comprises information about whether the second capacitor and the third capacitor of the capacitor bank have changed from the first state to the second state.

19. The method of claim 18, wherein determining whether the first capacitor of the capacitor bank has changed from the first state to the second state comprises:
generating a measured value based on the first representation; and
determining whether the measured value is outside a range of threshold values.

20. A computer readable medium comprising computer readable program code embodied therein for performing a method of validating an operation of a capacitor bank, the method comprising:
receiving a first representation from a first sensor at a first time, wherein the first sensor is operatively coupled to a first power line, wherein the first power line is electrically coupled to a first capacitor of the capacitor bank;
determining, based on the first representation, whether the first capacitor of the capacitor bank has changed from a first state to a second state; and
sending a first notification to a master controller, wherein the first notification comprises information as to whether the first capacitor of the capacitor bank has changed from the first state to the second state.
